(19) United States
(12) Patent Application Publication
(10) Pub. No.: US 2017/0241032 A1
(43) Pub. Date: Aug. 24, 2017

(54) METHOD FOR CONTROLLING CAVITY CLOSURE BY NON-CONFORMAL DEPOSITION OF A LAYER

(71) Applicant: COMMISSARIAT A L'ENERGIE ATOMIQUE ET AUX ENERGIES ALTERNATIVES, Paris (FR)

(72) Inventor: Emmanuel ROLLAND, Jarrie (FR)

(73) Assignee: COMMISSARIAT A L'ENERGIE ATOMIQUE ET AUX ENERGIES ALTERNATIVES, Paris (FR)

(21) Appl. No.: 15/514,993

(22) PCT Filed: Oct. 1, 2015
(86) PCT No.: PCT/EP2015/072735

§ 371 Date: Mar. 28, 2017

(30) Foreign Application Priority Data
Oct. 3, 2014 (FR) 14 59507

(51) Int. Cl. C25D 5/02; B23P 15/26; H01L 23/473; C25D 7/12; C25D 5/48

(52) U.S. Cl. CPC C25D 5/022; C25D 7/123; C25D 5/48; H01L 23/473; B23P 15/26

(57) ABSTRACT

A method for producing a closed cavity on a substrate, including: a) forming a cavity surrounded by at least one block on a given face of a substrate, the cavity having an aspect ratio higher than a determined threshold; and b) depositing a closing layer on the at least one block surrounding the cavity, the aspect ratio of the cavity being such that in b), the closing layer does not entirely fill the cavity and an empty space in the cavity is maintained.

### TECHNICAL FIELD AND PRIOR ART

The invention relates to the field of production of devices formed from a substrate and including one or more closed cavities on one of the substrate faces, such cavities being then able to be maintained empty or used to enable a gas or liquid flow to pass, in particular to implement a heat exchanger for a micro-electronic device or a micro-system.

To produce one or more closed cavities on a substrate, one technique consists in forming these cavities for example by etching a face of the substrate and then in closing them by adding a cover.

Such a method requires an alignment between the cover which is added and the cavities. On the other hand, the surface state of the assembled faces of the cover and the substrate must be adapted such that after sealing, the cavities are hermetically closed. Finally, adding the cover can induce mechanical stresses on the substrate.

There is a problem in that a new method for producing one or more cavities on a substrate has to be found, which enables the previous problems to be overcome.

### DISCLOSURE OF THE INVENTION

One embodiment of the present invention first provides a method for producing one or more closed cavities from a substrate comprising the steps consisting of:

a) forming at least one block delimiting at least one cavity on a given face of a substrate, the cavity having an aspect ratio h/dc of its height h to its smallest dimension dc measured parallel to a main plane of the substrate,

b) forming by a non-conformal deposition a closing layer on the block(s) and above the cavity, the aspect ratio h/dc of the cavity being such that in step b), the closing layer does not fill this cavity and that an empty space in the cavity is maintained.

The closing layer is deposited on the substrate in a non-conformal way.

By non-conformal deposition, it is meant that the layer does not reproduce the topography of the given face. The closing layer can possibly partially fill the cavity, an empty space being however maintained in this cavity.

By cavity, it is meant a depressed structure such as a groove or a trench, having for example a cylindrical shape, formed in a substrate.

This substrate can be formed of a single block or of a stack of layers.

The given face of the substrate can be the upper face also referred to as the front face of the substrate on which one or more electronic or electro-mechanical components are produced or intended to be produced. These electronic components are formed in particular in a semiconducting layer resting on the upper face.

Advantageously, depositing the closing layer is performed in step b) by electrolysis.

In this case, between step a) and step b), a conformal deposition of a conducting layer can be performed beforehand on the given face, the conducting layer covering the blocks, the bottom and the walls of the cavity, deposition of the closing layer being then performed in step b) by electrolysis on this conducting layer.

The advantage of an electrolytic deposition is to enable cavities having a significant critical dimension, in particular higher than 10 μm, to be closed without filling them.

After forming the conducting layer and prior to step b), at least one mask element can be formed on the given face of the substrate on which an electrolytic growth is prevented.

This in particular enables some areas of the substrate to be protected from the deposition.

The mask element enabling an area of the substrate to be masked during the electrolysis can then be removed after step b).

After removing the mask element, etching the conducting layer can be performed.

According to the aimed applications, maintaining this conductive layer can be chosen.

Another possible implementation of the closing layer comprises a physical vapour deposition in step b).

After step b), etching one or more areas of the closing layer can be performed. This step can enable some areas of the substrate to be stripped, or even some cavities to be opened.

In step a), the block(s) are formed by etching the given face of the substrate or by feeding material on the given face of the substrate.

According to a particular embodiment, the present invention provides the production of a heat exchanger structure for an electronic device and/or a micro-system comprising forming one or more closing cavities formed using the method such as defined above.

According to a possible implementation of the method wherein the substrate includes a semiconducting layer and wherein one or more transistors are able to be formed, the semiconducting layer having formed thereon an insulating layer in which one or more openings are made on either side of a set of blocks:

the closing layer in step b) can be formed in the openings so as to be in contact with the semiconducting layer.

### BRIEF DESCRIPTION OF DRAWINGS

The present invention will be better understood upon reading the description of exemplary implementations given, by way of purely indicating and in no way limiting purposes, with reference to the accompanying drawings in which:

FIGS. 1A-1F are used to illustrate a first exemplary method for producing closed cavities;

FIGS. 2A-2B are used to illustrate an alternative of the first exemplary method;

FIGS. 3A-3D are used to illustrate a second exemplary method for producing closed cavities;

FIGS. 4A-4B are used to illustrate an alternative of the second exemplary method;

FIG. 5 illustrates an exemplary implementation of the heat exchanger structure on the front face of a substrate;

FIGS. 6A-6B illustrate another exemplary implementation of the heat exchanger structure on the front face of a substrate.

Identical, similar or equivalent parts of the different figures bear the same reference numerals so as to facilitate switching from one figure to the other.

The different parts represented in the figures are not necessarily formed to a uniform scale, in order to make the figures more understandable.

### DETAILED DISCLOSURE OF PARTICULAR EMBODIMENTS

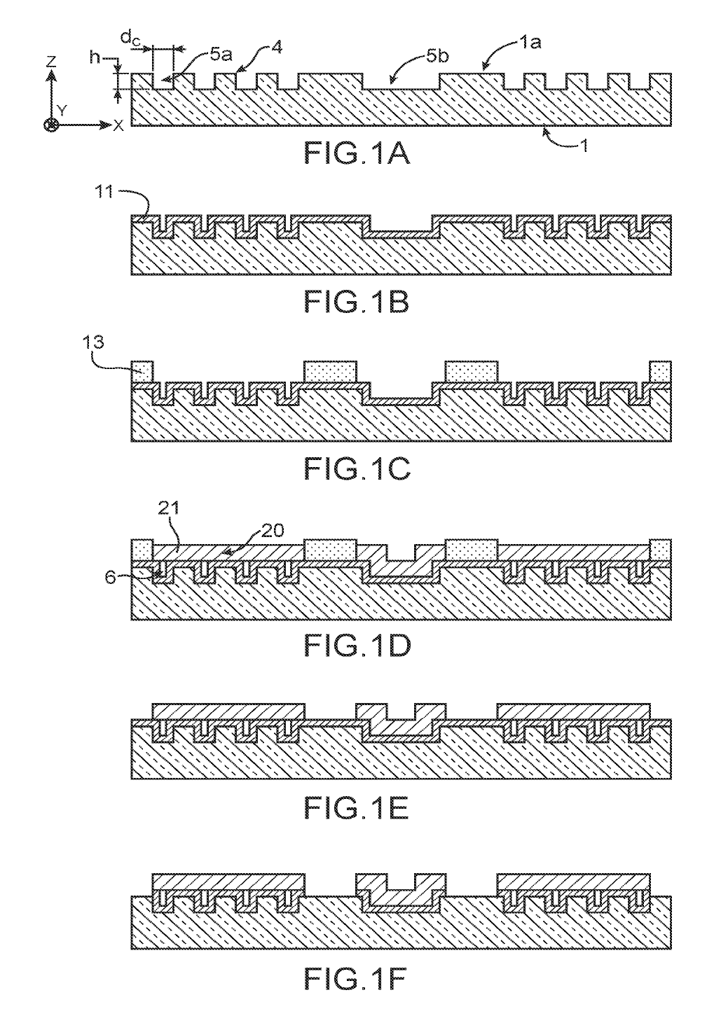

A first exemplary method for producing one or more closed cavities on a substrate will now be described in relation with FIGS. 1A-1F.

The starting material for this method is a substrate 1 which can be based on a semiconducting material, for example such as Si, and includes one or more patterns in the shape of one or more cavities 5a, 5b formed by etching through a face 12a also referred to as the “front face” or “upper face” of the substrate. The front face 1a is here a face on which one or more electronic and/or electro-mechanical components are produced or intended to be produced.

Cavities 5a, 5b are each delimited and surrounded by one or more blocks 4 etched in the substrate 1. One or more given cavities 5a are provided with an aspect ratio h/d_{c}, i.e. of their height h (measured in a direction parallel to a vector z of an orthogonal reference plane [O; x; y; z] given in FIG. 1A) to their width also referred to as the “critical dimension” dc, h/d_{c} being provided higher than a determined threshold. By “width” or “critical dimension” dc, it is here meant and throughout the description the smallest dimension of a pattern except its height or its thickness (dc being here measured in a plane parallel to the main plane of the substrate, i.e. a plane passing through the substrate and parallel to the plane [O; x; y]).

The given cavities 5a have a critical dimension dc which can be between 0.05 μm and 100 μm and a height which can be for example between 0.05 μm and 700 μm. In a case where for example the substrate 1 is a 300 mm Si plate having a thickness in the order of 772 μm, the cavities have a height which can be for example in the order of a few micrometres shorter, for example in the order of 700 μm. According to another example, in the case when the substrate 1 is made from glass and has a thickness of 1200 μm, the cavities can have a height in the order of 1190 μm.

A conducting layer 11 is then produced on the front face 1a of the substrate 1 (FIG. 1B). This conducting layer 11 can be formed of a stack comprising a metal diffusion barrier sublayer, for example made from titanium. This barrier sublayer can also act as a layer for adhering to another metal layer formed thereon. This other metal layer can be for example made from copper. The conducting layer 11 is produced by a conformal deposition such that it reproduces the relief of the front face 1a of the substrate 1. The thickness of the conducting layer 11 is provided so as to cover the bottom and the side walls of the cavities 5a, 5b, without entirely filling them.

A layer 20 for closing the cavities is then formed. In this exemplary implementation, the closing layer 20 is formed by electrolytic deposition, the deposition being non-conformal.

In a case where it is desired to deposit the closing layer 20 only on certain localised regions of the front face 1a of the substrate, this deposition can be preceded by forming masking patterns 13, which can be for example produced by photolithography (FIG. 1C). The masking patterns 13 are made from a material which is not conducting and on which an electrolytic growth is prevented. The masking can be for example a dielectric material or a polymer, in particular a photoresist. The layer 20 for closing the cavities can be made from a metal material such as for example copper or nickel.

Due to the aspect ratio h/dc of the given cavities 5a, the deposited closing layer 20 enables these cavities 5a to be closed or sealed without entirely filling them (FIG. 1D). An empty space 6 delimited between the side walls, the bottom of the cavities 5a covered with the conducting layer 11 and the closing layer 20 is thus maintained.

The aspect ratio threshold beyond which it is provided to form the cavities 5a can depend on the type of deposited material and on the thickness provided for the closing layer 20. Sealing the cavities 5a having a critical dimension dc between for example 0.05 μm and 100 μm can be performed. For example, a cavity 5a formed by electrolysing a deposited copper layer having a width dc of 0.25 μm can be provided with a height h in the order of 1.5 μm. The ratio dc/h is chosen preferably higher than ½ to promote the closing of cavities without entirely filling them.

Parameters for forming the electrolytic deposition are adapted to make it non-conformal so that this deposition is promoted on the upper part of the walls of the cavity which will thus be closed without being entirely filled.

By way of example to promote forming closed cavities 5a but not filled with material 20, it can be provided to perform the electrolytic deposition by adapting the electrolyte and/or its additives and/or the current of the electrolysis. The higher a current is provided, the more a non-conformal deposition is promoted so as to perform closing of a cavity without filling it. For example, for deposing a closing layer made from Cu, a current between 1 mA/cm² and 100 mA/cm² can be used. In this case, a value of 100 mA/cm² is then promoted.

Certain cavities 5a having a lower aspect ratio less than a determined threshold, can be filled by the material of the closing layer 20.

In the case when a localised electrolytic deposition has been performed, the masking blocks 13 are then removed using a dry and/or wet etching (FIG. 1E).

Removing the masking blocks 13 can be performed, for example through a method commonly referred to as “stripping” when these masking blocks 13 are made of resin.

If necessary, the conducting layer 11 can then be etched (FIG. 1F). An anisotropic etching can be made so as to maintain only the conducting layer 11 facing the areas of the closing layer 20.

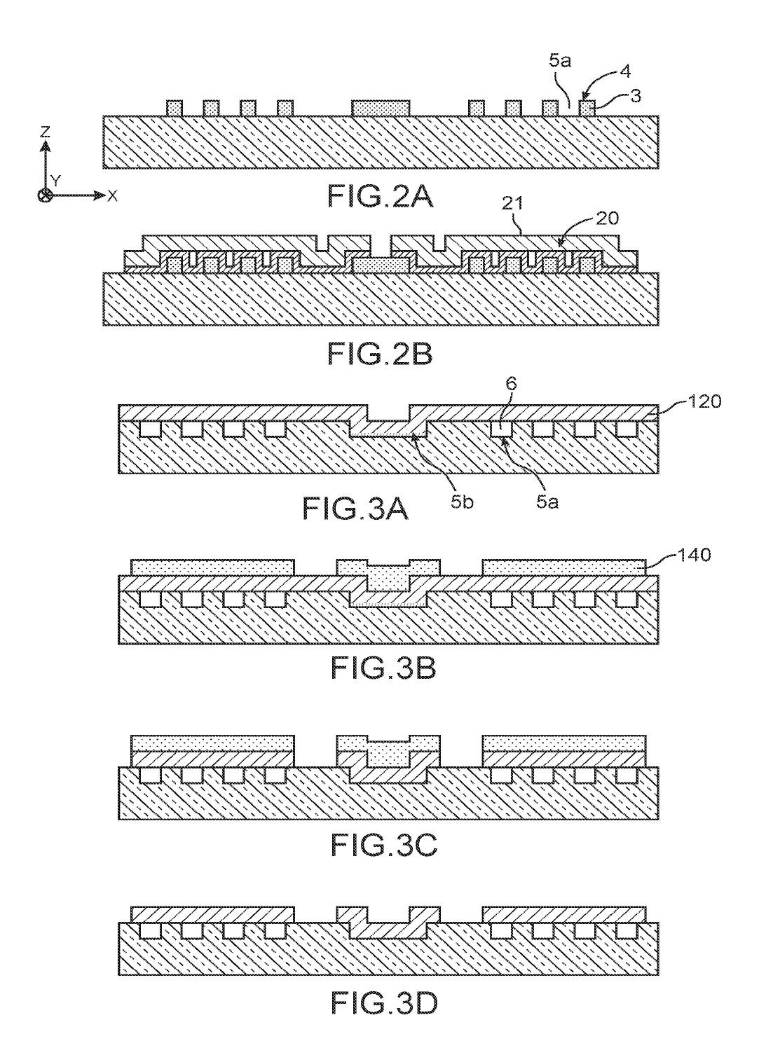

An alternative method illustrated in FIGS. 2A-2B provides forming cavities 5a, 5b in a layer of material 3 added on a substrate 1, for example by deposition, and in which patterns are formed, for example by etching. The other steps of this alternative can follow those of the example previously described in relation with FIGS. 1A-1F.

According to an alternative of either one of the previously described examples, a layer 120 for closing cavities 5A, 5b can be formed by a physical vapour deposition, PVD.

This deposition can be performed on a front face 1a of the substrate 1 in which the cavities have been formed by etching the substrate (FIG. 3A). PVD deposition is non-conformal and can be performed at a lower pressure (i.e. lower than 1 mBar) in an enclosure under partial vacuum. Due to the aspect ratio h/dc of given cavities 5a, the deposited closing layer 120 enables these cavities 5a to be closed or sealed without entirely filling them. Closed or sealed cavities 5a thus include an empty space 6.

Other cavities 5b having a lower aspect ratio less than a determined threshold are as for them filled with the material of the closing layer 120.

In particular, these other cavities 5b have a width or critical dimension higher than the one of cavities 5a and a height which can be equal to those of cavities 5a.

Then, patterns can be made in the closing layer 120 by etching it for example through openings of a masking 140. This masking 140 can be made for example from a photosensitive polymer and performed by photolithography (FIGS. 3B-3C).

Masking 140 can then be removed (FIG. 3D). Closing areas 120a are thus obtained enabling one or more localised cavities 5a to be sealed without entirely filling them.

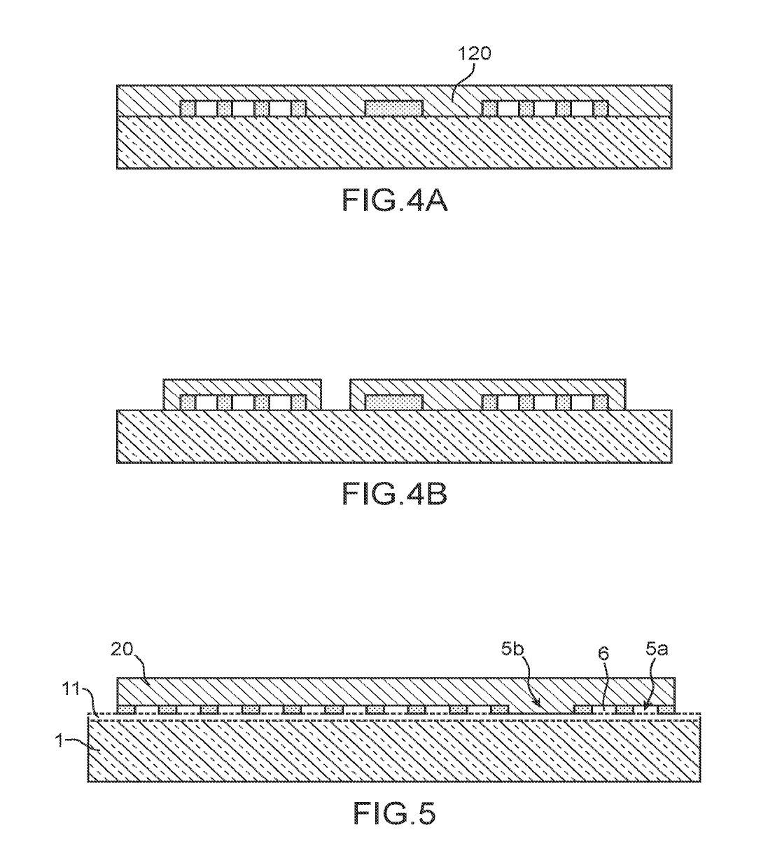

FIGS. 4A-4B illustrate an alternative implementation of the closing layer 120 by PVD on cavities 5a, 5b formed in a layer 3 added or deposited on the front face of the substrate 1.

A method according to the invention can have applications in producing a device with closed cavities and producing channels for circulating a substance (gas, liquid, molecule(s), organic matter) next to the active device.

FIG. 5 illustrates an exemplary heat exchanger structure formed using a method such as previously described.

This structure also includes a layer 20 for closing cavities 5a, 5b disposed at the front face 1a of a substrate 1. This front face 1a is covered with a stack 11 of layers in which electronic components such as transistors in CMOS technology are formed. Some cavities 5a disposed on and/or facing the components, include an empty space 6 forming a channel in which a fluid is intended to circulate.

Due to its proximity to the components, this structure can thus enable a heating of a micro-electronic device disposed on the upper face 1a of the substrate 1 to be restricted.

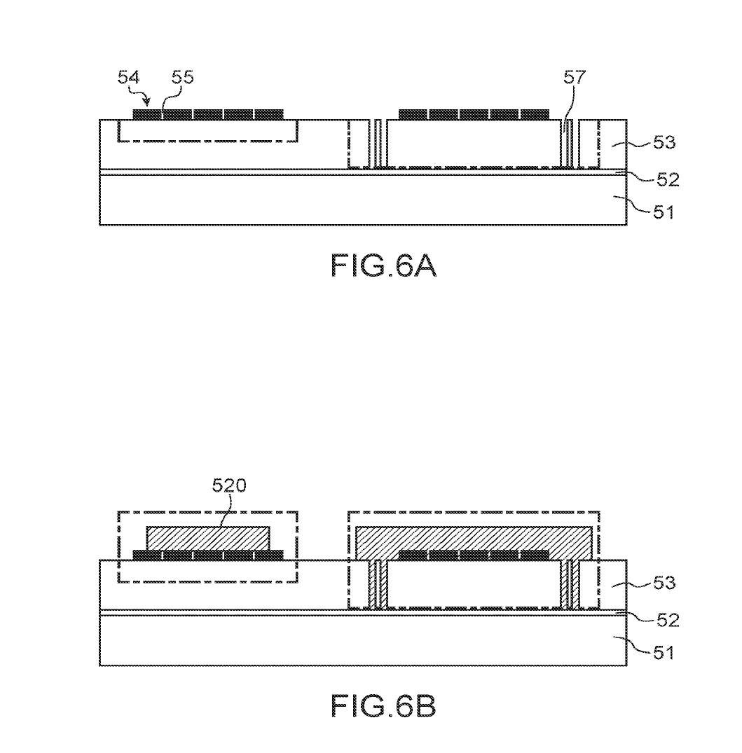

Another exemplary method for producing a structure provided with one or more closed cavities on a substrate will now be described in relation to FIGS. 6A-6B.

We start this time with a substrate 51 which can be a bulk semiconducting substrate made of a semiconducting material, for example such as Si and the front or upper face of which includes at least one semiconducting layer 52 in which one or more electronic components are able to be formed, in particular transistors for example in the CMOS technology. The semiconducting layer 52 has itself formed thereon at least one layer 53, which can have a thickness in the order of several micrometres, for example in the order of 7 μm. The layer 53 is comprised of encapsulated interconnect lines in at least one insulating layer. This layer 53 is typically referred to as BEOL (back end of lines) in a CMOS technology. BEOL is typically comprised of 7 levels of interconnect lines each separated by an insulator layer. The layer 53 is in this example covered with blocks 54 between which cavities 55 are delimited. The blocks 54 are made in a conducting layer, for example a metal layer belonging to a given interconnect level of components and covered with an insulating layer also called a passivation layer.

Cavities 55 are preferably provided with an aspect ratio h/d_{c}, higher than the determined threshold discussed in the described exemplary implementations.

On either side of a first set of blocks 54, openings 57 passing though the layer 53 are made. At the bottom of these openings 57, the semiconducting layer 52 in which the CMOS transistors are formed is revealed.

Then a layer 520 for closing cavities is formed. The closing layer 520 is made of a conducting or metal material and is made for example by electrolytic deposition.

The closing layer 520 can be made as in the example of FIG. 1D, on a thin conformal conducting layer (not represented in FIGS. 6A-6B) reproducing the relief of the front face of the substrate which has been deposited beforehand.

In the exemplary implementation of FIG. 6B, the closing layer 520 is only disposed on certain localised regions where the sets of blocks 54 are disposed. This localised disposition can be implemented using a method in which a masking (not represented) is formed on certain portions of the insulating layer 53 or by performing etching of parts of the closing layer 520, for example through a mask. Depositing the closing layer 520 is then performed so as to fill the openings 57 passing through the insulating layer 53 of a conducting material. The closing layer 520 thus produced is therefore in contact with the semiconducting layer 52. Elements 522 of the closing layer 520 disposed in the openings enable the exchanger structure to be linked with the semiconducting layer in which transistors are formed.

A thermal heating of this semiconducting layer 52 spreads in the closing layer 520 of the heat exchanger structure with closed cavities 55. A thermal dissipation is thus produced thanks to the cavities 55 in which air or a gas or a cooling fluid can circulate.

1-9. (canceled)

10. A method for producing a heat exchanger structure including one or more closed cavities, the method comprising:
a) forming at least one block delimiting at least one cavity on a given face of a substrate, the cavity having an aspect ratio h/dc of its height h to its smallest dimension dc measured parallel to a main plane of the substrate;
b) forming by an electrolytic deposition a closing layer on the at least one block and above the cavity,
the aspect ratio h/dc of the cavity being such that in b), the closing layer does not fill the cavity and an empty space in the cavity is maintained.

11. The method according to claim 10, wherein between a) and b), a conformal deposition of a conducting layer is performed on the given face, the conducting layer covering the at least one block and a bottom and walls of the cavity, the depositing the closing layer being then performed in b) by electrolysis on the conducting layer.

12. The method according to claim 11, wherein after forming the conducting layer and prior to b), at least one mask element is formed on the given face of the substrate, on which an electrolytic growth is prevented.

13. The method according to claim 12, wherein the mask element is removed after b).

14. The method according to claim 13, further comprising, after removing the mask element, etching the conducting layer.

15. The method according to claim 10, further comprising, after b), performing localized etching of the closing layer outside the cavity.

16. The method according to claim 10, wherein in a), the at least one block is formed by etching the given face of the substrate or by feeding material on the given face of the substrate.

17. The method according to claim 10, wherein the given face is a substrate face on which one or more electronic or electro-mechanical components are produced or intended to be produced.

18. The method according to claim 10, wherein the substrate includes a semiconducting layer, and in which one or more transistors can be formed, the semiconducting layer having formed thereon a layer in which one or more openings are made on either side of a set of blocks, the closing layer in b) being formed in the openings.
